(19) United States
(12) Patent Application Publication
(10) Pub. No.: US 2021/0170771 A1
(43) Pub. Date: Jun. 10, 2021

(54) MOTOR IDENTIFICATION WITH MULTIPLE MOTORS

(71) Applicant: HEWLETT-PACKARD DEVELOPMENT COMPANY, L.P., Spring, TX (US)

(72) Inventors: Carles Flotats Villagrasa, Sant Cugat del Valles (ES); Aleix Fort Filgueira, Sant Cugat del Valles (ES); Jordi Hernandez Creus, Sant Cugat del Valles (ES)

(73) Assignee: HEWLETT-PACKARD DEVELOPMENT COMPANY, L.P., Spring, TX (US)

(21) Appl. No.: 16/768,823

(22) PCT Filed: Dec. 18, 2017
(86) PCT No.: PCT/US17/67069

§ 371 Date: Jun. 1, 2020

(51) Int. Cl. B41J 29/393; G01R 31/34

(52) U.S. Cl. CPC B41J 29/393; G01R 31/343

(57) ABSTRACT

It is disclosed a motor identification method for determine possible incorrect connections in a system comprising a plurality of motors corresponding to a plurality of sub-systems, the method comprising: applying an input to at least one of the motors causing its movement; and determining a detection signal corresponding to a position, speed or acceleration of the motor during a detection period; wherein the system comprises a memory storing a set of characteristic signals corresponding to at least some of the sub-systems and wherein the method comprises comparing, by a controller, the detection signal with the set of characteristic signals and correlating the at least one of the motors to a determined sub-system.

### BACKGROUND

Multi-motor systems often comprise a common board for the control of several motors. An example of a multi-motor system is a printer wherein several motors of similar types and power ratings are used for different purposes, for example, 12 to 42 V continuous current motors with powers between 50 to 450 W are often used for media input as a rewinder motor and, also, are used for pushing paper towards the printer as roller motors.

### BRIEF DESCRIPTION OF THE DRAWINGS

FIG. 1 shows an example of an architecture with multiple motors.

FIG. 2 shows an example of a motor identification method.

FIG. 3 shows a further example of a motor identification method.

FIG. 4 shows examples of characteristic signals that may be identified according to a motor identification method.

### DETAILED DESCRIPTION

The control of systems with multiple motors is often performed by configuring a software or firmware to correlate a set of motors with their corresponding encoder and with their corresponding function within the system.

Performing mounting or maintenance operations on a system with multiple motors is subject to human errors, e.g., an incorrect connection of the motors and/or encoders to their corresponding location within the board thereby causing a malfunctioning of the system.

In the foregoing, reference is made to the accompanying drawings. The examples in the description and drawings should be considered illustrative and are not to be considered as limiting to the specific example or element described. Multiple examples may be derived from the following description and/or drawings through modification, combination or variation of certain elements. Although certain features are shown and described in conjunction, they may be applied separately to the methods and/or systems of this description, also if not specifically claimed. Furthermore, it may be understood that examples or elements that are not literally described may be derived from the description and drawings by a person with ordinary skill in the art.

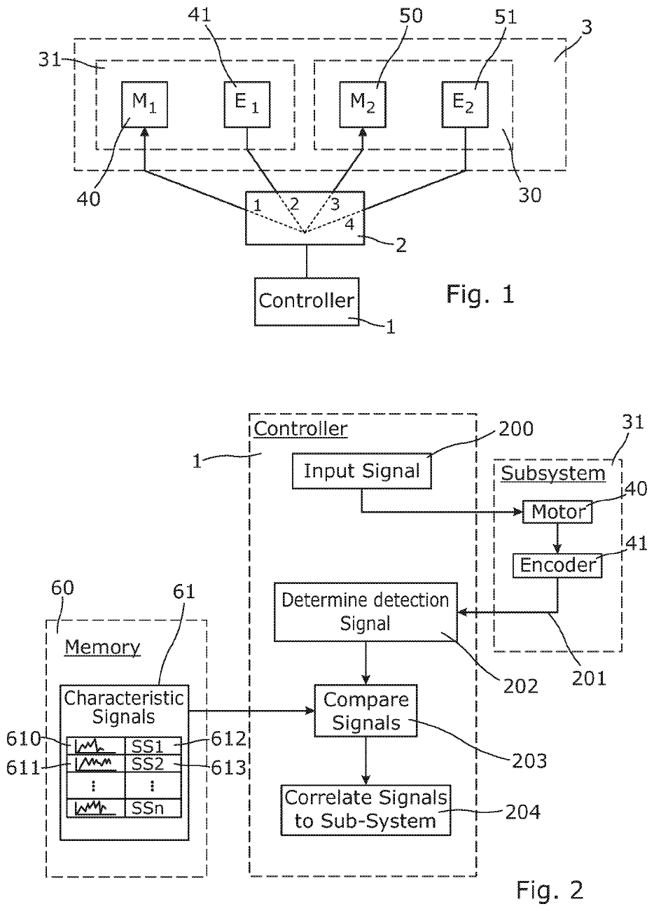

FIG. 1 shows an example of an architecture wherein several motors may be provided within a system 3. The system 3 of FIG. 1 comprises a sub-system 31 with a motor 40 and a corresponding encoder 41 and a second sub-subsystem 30 with a second motor 50 and a second corresponding encoder 51.

All of these elements are connected to a common board 2 which has a set of input/output ports, four in the case of FIG. 1, each assigned to the previously described elements.

The motors 40, 50 are often similar types of motor with similar power ratings but are connected to different subsystems 30, 31. During maintenance some of the elements may be incorrectly connected by the user to different port. In that case, a motor identification method may be used to determine that an incorrect connection has been performed or reassign the addresses in a controller 1 to accommodate the new operating conditions of the system 3 and, in particular, the new addresses for the elements connected to the board 2.

Each sub-system comprises a unique set of associated mechanical elements, therefore, the response of each sub-system to a specific motion of the motor (e.g., its speed, angular position, or acceleration) is also unique. For example, the mechanical elements connected to a take-up reel are different to those connected to a stacker, therefore, even if the sub-systems are connected to the same type of motor, their response to a specific motion of the motor is different.

By analyzing a response of each motor, e.g., by collecting detection signals from the encoders 41, 51 for a determined input signal, the controller 1 has a manner of identifying which sub-system 30, 31 is connected to a determined motor 40, 50 and may be able to reassign the addresses of the board to virtually correct the incorrect connection without user interaction, e.g., in the firmware of the system.

FIG. 2 shows an example of a method to identify a motor within a system. In the example of FIG. 2, a controller 1 issues an input signal that is sent to a motor 40 mechanically coupled to a sub-system 31. In response to such input signal the motor performs a rotation that is measured by an encoder 41 which issues a detection signal 201 that is sent back to the controller 1 for processing. The controller 1 may then receive and determine the detection signal 202.

In the example of FIG. 2, the system comprises a memory 60 wherein a set of characteristic signals 61 are stored. These characteristic signals 61 comprise a plurality of motor responses 610, 611 and their corresponding subsystem identifications 612, 613 that may be input to the memory, e.g., during a firmware set-up or firmware update. The motor responses 610, 611 may be acquired, for example, during a factory set-up, manufacturing process, through characterization of prototypes/production units and/or by analysis of data extracted from working units. In an example, the motor responses 610, 611 are encoder measurements made on motors in response to a determined input.

The controller 1 receives the set of characteristic signals 61 from the memory 60 and, on the other, the detection signal 201 corresponding to the motor 40 of the subsystem 31. Subsequently, the controller compares the detection signal 201 for the motor 40 (or any other motors connected to the board) to the motor responses 610, 611. Once a match is detected, the controller 1 determines the sub-system identification 612, 613 related to the motor response 610, 611 with a match, and correlates 204 the detection signal 201 to the determined sub-system identification 612, 613.

With this correlation, the controller 1 has identified the sub-system that corresponds to the motor and may be able to, for example, modify the firmware of the system to assign which output port of the board corresponds to each sub-system. For example, modifying a piece of software, a piece of hardware and/or a memory location so that every time a signal is to be sent to a motor it is sent to the assigned port. Also, the controller may be able to assign if a port is an input port or an output port.

The input signal may be, e.g., a pulsed width modulation (PWM) signal, in an example, the PWM signal comprises multiple frequencies. The detection signal 201 may be, e.g., a position or speed signal measured during a detection period and may be measured in encoder steps or encoder steps per unit of time respectively.

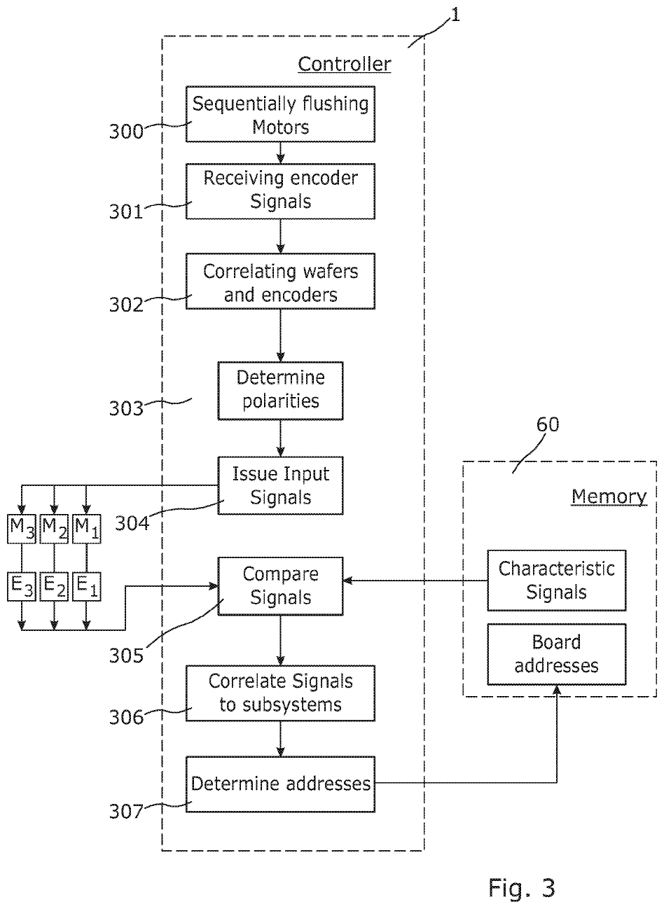

FIG. 3 shows a further example of a motor identification method. In the method of FIG. 3, the controller 1 is to sequentially move the motors 300 and then, for each movement receive encoder signals 301, in this way, the controller 1 is able to identify which encoder corresponds to a particular motor and is able to correlate the motors to the encoders 302.

Also, from this initial movement of the motors and using the encoder signals, the polarity of the motors is determined 303 and may be corrected on firmware or notifying the user that a change in the connections should be performed.

Subsequently, the controller 1 issues an input signal 304 to a series of motors M₁, M₂, M₃ within the system, being the system also provided with encoders E₁, E₂, E₃ to detect the position and/or speed of such motors respectively. Then, the controller 1 reads from each of the encoders E₁, E₂, E₃ a detection signal 201 and from the memory the characteristic signals 61, more specifically, the motor responses within such characteristic signals 61 as explained with reference to FIG. 2.

Then, a correlation 306 is performed between the detection signals 201 and the characteristic signals 61 which results in a sub-system (or a sub-system identification) assigned to each motor-encoder pair.

Finally, by having this correlation between each the motor-encoder pairs and the sub-system wherein they are connected the controller may determine the addresses 307 within the firmware so that the system can use the appropriate addresses when operating on the system and storing them on a memory (e.g., the memory 60) as board addresses 62.

Also, this method may also help identify possible mechanical/electrical damages that may be present on the sub-systems, for example, if the motor responses do not match any of the characteristic signals an alert may be prompted to the user for manual identification or for performing an inspection in the sub-system.

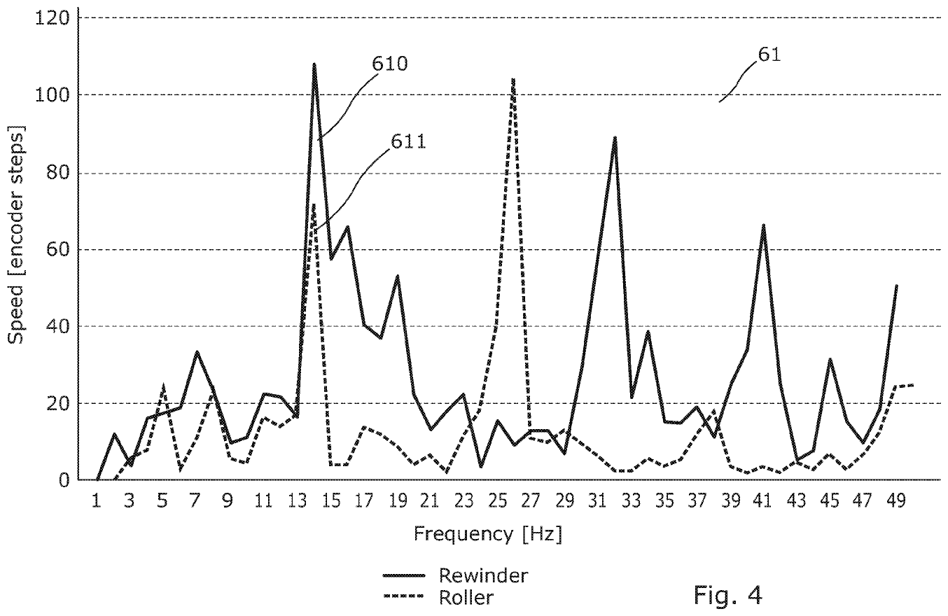

FIG. 4 shows a graph wherein two examples of motor responses 610 611 for use as part of the characteristic signals 61 are superposed.

In the example of FIG. 4, a first motor response 610 is collected for a DC motor with a 96:1 reduction ratio through three stages of gears connected to a rewinder assembly within a printing systema and a second motor response 611 is collected for a DC motor with a worm gear and a 40 teeth reduction gear connected to a roller assembly. As can be seen from FIG. 4, even though the motors are substantially the same, the motor responses 610, 611 depend largely on the sub-system (mostly, the mechanical elements) to which the motors are connected. Therefore these motor responses, that are basically a Fourier transform, can be used as a frequency fingerprint that may be, at least, partially stored in the memory 60 in the form of a characteristic signal 61 and may be correlated to the sub-systems. Then, for example, during a booting sequence of the system, these responses may be acquired for the plurality motors as to identify the sub-systems to which they are connected and reroute the addresses within a software/firmware to virtually correct any possible incorrect connection by a user.

In essence, it is disclosed a motor identification method for a system comprising a plurality of motors corresponding to a plurality of sub-systems, the method comprising:
applying an input to a first motor of the plurality of motors causing an operation of the first motor; and
obtaining a detection signal corresponding to a characteristic of the first motor during a detection period;
comparing, by a controller, the detection signal with a set of characteristic signals stored on a memory of the system, the set of characteristic signals including a first characteristic signal corresponding to a first sub-system of the plurality of sub-systems;
determining whether the first detection signal corresponds to the first characteristic signal; and
correlating the first motor to the first sub-system as determined by the controller.

In an example, the characteristic of the first motor comprises the speed, position and/or acceleration of the first motor.

In a further example, the method is performed during a booting sequence or a diagnostic sequence.

As for the input, it may be supplied by a source with at least a magnitude variation during the detection period, e.g., the input may be a PWM signal or an AC signal with a varying frequency or a DC voltage with varying voltage magnitudes during a determined period.

In a further example, the memory comprises a set of motor responses and a corresponding sub-system identification, wherein the comparing is performed between the detection signal and the motor response and wherein the correlating is performed by assigning the corresponding sub-system identification to a matching detection signal.

The detection signal may be determined, e.g., by an encoder.

Also, the method may comprise further detection features, e.g., by sequentially moving some of the plurality of motors and determining an encoder associated to some of the plurality of motors and, in a further example, their polarity. Moreover, the system may comprise a second motor and the method may comprise sequentially moving the first and the second motor and determining an encoder associated to the first motor or the second motor

Furthermore, the controller may have access to a set of addresses, e.g., board addresses corresponding to each sub-system and the method comprises selecting the address of the at least some of the plurality of motors. Such addresses may be stored in a further memory or in the memory wherein the characteristic signals are stored.

In an example, the plurality of motors are a plurality of direct current motors. Also, the system may be, e.g., a printing system.

It is also envisaged a printing system comprising a memory with a set of characteristic signals stored thereon, each characteristic signal being associated with a sub-system identification field, a plurality of motors corresponding to a plurality of subsystems, and a controller to:
issue an input signal to the plurality of motors;
receive a plurality of detection signals from the plurality of motors corresponding to the position, speed, or acceleration of the plurality of motors;
determine a correlation between the plurality of detection signals and the plurality of characteristic signals; and
assign the sub-system identification field associated with the corresponding characteristic signals to the plurality of motors for which a correlation of the corresponding detection signal was determined.

As mentioned above, in an example, the detection signals are issued by encoders.

Also, the input signal to the plurality of motors may be issued by a source with at least a magnitude variation and/or a phase variation.

In an example, the assigning of the sub-system identification field comprises changing addresses in a printer firmware

1. A motor identification method for a system comprising a plurality of motors corresponding to a plurality of sub-systems, the method comprising:
applying an input to a first motor of the plurality of motors causing an operation of the first motor; and
obtaining a detection signal corresponding to a characteristic of the first motor during a detection period;
comparing, by a controller, the detection signal with a set of characteristic signals stored on a memory of the system, the set of characteristic signals including a first characteristic signal corresponding to a first sub-system of the plurality of sub-systems;
determining whether the first detection signal corresponds to the first characteristic signal; and
correlating the first motor to the first sub-system as determined by the controller.

2. The method of claim 1, wherein the characteristic of the first motor comprises the speed, position and/or acceleration of the first motor.

3. The method of claim 1 wherein the method is performed during a booting sequence or a diagnostic sequence.

4. The method of claim 1 wherein the input is supplied by a source with a magnitude variation during the detection period.

5. The method of claim 1 wherein the input is supplied by a source with a frequency variation during the detection period.

6. The method of claim 1 wherein the memory comprises a set of motor responses and a corresponding sub-system identification, wherein the comparing is performed between the detection signal and the motor response and wherein the correlating is performed by assigning the corresponding sub-system identification to a matching detection signal.

7. The method of claim 1 wherein the detection signal is determined by an encoder.

8. The method of claim 1 wherein the system further comprises a second motor and the method comprises sequentially moving the first and the second motor and determining an encoder associated to the first motor or the second motor.

9. The method of claim 1 wherein the controller has access to a set of addresses corresponding to each sub-system and the method comprises selecting the address of the at least some of the plurality of motors.

10. The method of claim 1 further comprises sequentially moving at least some of the plurality of motors and determining the polarity of each of the at least some of the plurality of motors

11. The method of claim 1 wherein the plurality of motors are a plurality of direct current motors.

12. The method of claim 1 wherein the system is a printing system.

13. Printing system comprising a memory with a set of characteristic signals stored thereon, each characteristic signal being associated with a sub-system identification field, a plurality of motors corresponding to a plurality of sub-systems, and a controller to:
issue an input signal to the plurality of motors;
receive a plurality of detection signals from the plurality of motors corresponding to the position, speed, or acceleration of the plurality of motors;
determine a correlation between the plurality of detection signals and the plurality of characteristic signals; and
assign the sub-system identification field associated with the corresponding characteristic signals to the plurality of motors for which a correlation of the corresponding detection signal was determined.

14. The printing system of claim 12, wherein the detection signals are issued by encoders.

15. The printing system of claim 12, wherein the input signal to the plurality of motors is issued by a source with at least a magnitude variation and/or a phase variation.

16. The printing system of claim 12, wherein the assigning of the sub-system identification field comprises changing addresses in a printer firmware.
